(19) United States
(12) Patent Application Publication
(10) Pub. No.: US 2025/0163570 A1
(43) Pub. Date: May 22, 2025

(54) METHOD AND APPARATUS OF EMBEDDING RUTHENIUM INTO RECESS

(71) Applicant: Tokyo Electron Limited, Minato-ku, Tokyo (JP)

(72) Inventors: Masato ARAKI, Nirasaki City, Yamanashi (JP); Tadahiro ISHIZAKA, Nirasaki City, Yamanashi (JP)

(21) Appl. No.: 18/837,713

(22) PCT Filed: Jan. 31, 2023
(86) PCT No.: PCT/JP2023/003057

§ 371 Date: Aug. 12, 2024

(30) Foreign Application Priority Data
Feb. 14, 2022 (JP) 2022-020708

(51) Int. Cl. C23C 16/04; C23C 16/18

(52) U.S. Cl. CPC C23C 16/045; C23C 16/18

(57) ABSTRACT

A method of embedding ruthenium into a recess formed in an insulation film on a substrate, includes: forming a first ruthenium film by supplying a ruthenium raw material to the substrate so that the ruthenium is embedded into the recess; after stopping the forming the first ruthenium film, etching the first ruthenium film by supplying an ozone gas to the substrate until a sidewall of the recess is exposed while leaving the ruthenium embedded at a bottom portion of the recess; and subsequently, forming a second ruthenium film by supplying the ruthenium raw material to the substrate so that the recess is filled with ruthenium.

### TECHNICAL FIELD

The present disclosure relates to a method and apparatus of embedding ruthenium into a recess.

### BACKGROUND

In the manufacturing process of semiconductor devices, there is a process of forming recesses such as holes or trenches in an insulation film formed on a substrate used for manufacturing semiconductor devices, and forming a ruthenium film to embed ruthenium (Ru), which serves as a wiring material, into the recesses.

Patent Document 1 discloses a technique for selectively forming a target film (e.g., Ru film) in a first region on a surface of a substrate, the substrate having the first region where a conductive material (e.g., Ru) is exposed and a second region where an insulating material (e.g., Low-k material) is exposed. Further, Patent Document 1 discloses supplying an ozone gas to the substrate before forming the target film to increase the number of OH groups on a surface of the insulating material, thereby increasing the selectivity of the formation of the target film in the first region.

### PRIOR ART DOCUMENT

### Patent Document

Patent Document 1: Japanese Laid-Open Patent Publication No. 2020-147829

### SUMMARY

The present disclosure provides a technique for embedding ruthenium into a recess while suppressing the formation of voids.

According to the present disclosure, a method of embedding ruthenium into a recess formed in an insulation film on a substrate, includes: forming a first ruthenium film by supplying a ruthenium raw material to the substrate so that the ruthenium is embedded into the recess; after stopping the forming the first ruthenium film, etching the first ruthenium film by supplying an ozone gas to the substrate until a sidewall of the recess is exposed while leaving the ruthenium embedded at a bottom portion of the recess; and subsequently, forming a second ruthenium film by supplying the ruthenium raw material to the substrate so that the recess is filled with ruthenium.

According to the present disclosure, it is possible to embed ruthenium into a recess while preventing the formation of voids.

### BRIEF DESCRIPTION OF DRAWINGS

FIG. 1A illustrates a first example of an internal structure of a recess into which ruthenium is embedded according to the present disclosure.

FIG. 1B illustrates a second example of the internal structure of the recess into which the ruthenium is embedded.

FIG. 2 illustrates a configuration example of a film forming apparatus for performing the embedding of ruthenium.

FIG. 3 is a first operational view of a film formation process according to an embodiment.

FIG. 4 is a second operational view of the film formation process.

FIGS. 5A and 5B are third operational views of the film formation process.

FIG. 6 is a fourth operational view of the film formation process.

FIG. 7 is a fifth operational view of the film formation process.

FIG. 8 is a sixth operational view of the film formation process.

FIG. 9 is a graph illustrating a change in ruthenium film thickness in terms of a film formation cycle in Reference Example.

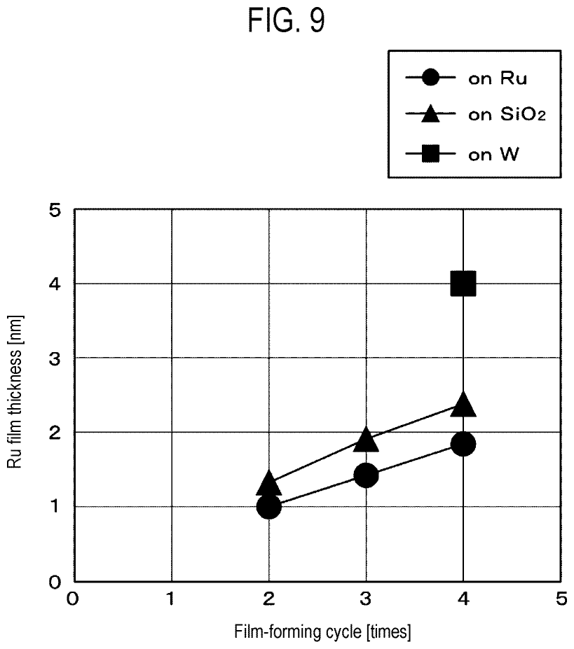

FIG. 10 is a graph illustrating a change in ruthenium film thickness in terms of a film formation cycle in Example.

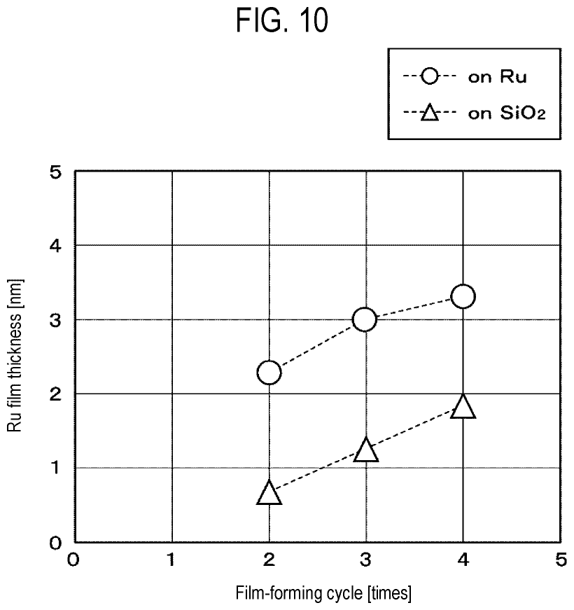

### DETAILED DESCRIPTION

### Surface Structure of Wafer

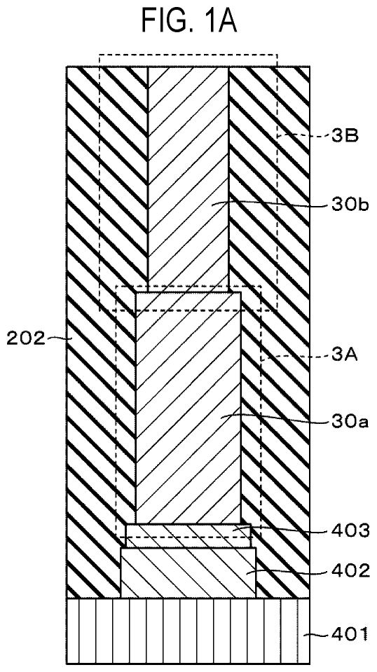

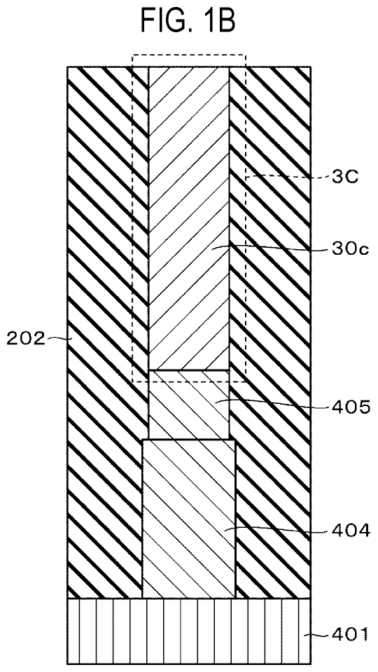

FIGS. 1A and 1B illustrate configuration examples of a recess formed in a silicon wafer (hereinafter referred to as “wafer”), which is a substrate where ruthenium is embedded according to the present disclosure.

For example, in metal oxide semiconductor field effect transistors (MOS-FETs) for logic elements, a metal for wiring is embedded into a recess formed in an interlayer insulation film to be connected to a diffusion layer. With the miniaturization of semiconductor devices, there is a demand for low-resistance of the metal for wiring, and therefore, ruthenium as a low-resistance material, has attracted attention.

FIGS. 1A and 1B illustrate structures where an insulation film 202 is formed on a silicon layer 401, which is a main body of a wafer W, and a recess is formed to penetrate through the insulation film 202.

An epitaxial layer 402 for making electrical contact with the silicon layer 401, a TiSiₓ layer 403, and a ruthenium 30a used for contact are stacked in this order from below in the recess formed in the insulation film 202 illustrated in FIG. 1A. Further, a ruthenium 30b used for plug is stacked on the ruthenium 30a to fill the remaining portion of the recess. In a configuration illustrated in FIG. 1A, a region where the ruthenium 30a is stacked on the TiSiₓ layer 403 and a region where the ruthenium 30b is stacked on the ruthenium 30a are referred to as ruthenium embedding regions 3A and 3B to which the present disclosure is applied.

Further, a metal gate 404 for making electrical contact with the silicon layer 401, and a tungsten layer 405 are stacked in this order from below in the recess of the insulation film 202 illustrated in FIG. 1B. Further, a ruthenium 30c is stacked on the tungsten layer 405. In a configuration illustrated in FIG. 1B, a region where the ruthenium 30c is stacked on the tungsten layer 405 is referred to as a ruthenium embedding region 3C to which the present disclosure is applied.

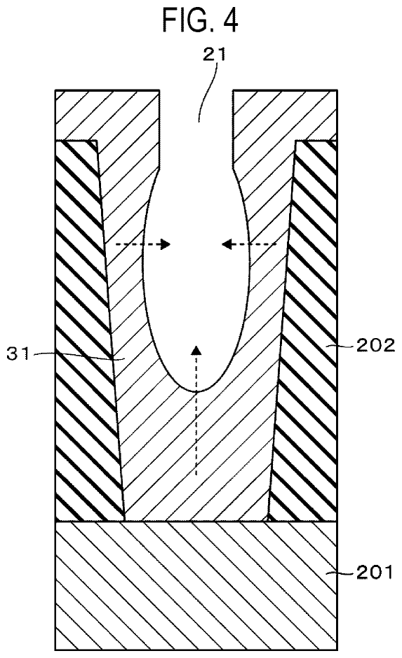

Here, when supplying a ruthenium raw material gas with respect to the wafer W to embed the ruthenium 30a to 30c into the recess, a film may be preferentially formed near an opening rather than an interior of the recess (see a first ruthenium film 31 in FIG. 4 to be described later). When the ruthenium film is continuously formed in this state, the entry of the raw material gas into the recess may be hampered, which may block the opening of the recess by the ruthenium film. The ruthenium film thus formed may greatly cause the formation of voids (empty spaces) in the ruthenium 30a to 30c embedded into the recess. The formation of the voids may cause an increase in resistance values of the ruthenium 30a to 30c as wiring materials.

Therefore, according to the present disclosure, when embedding the ruthenium 30a to 30c into the recess, an operation of partially etching the ruthenium film using an ozone (O₃) gas is performed to suppress the formation of the voids in the ruthenium 30a to 30c embedded into the recess.

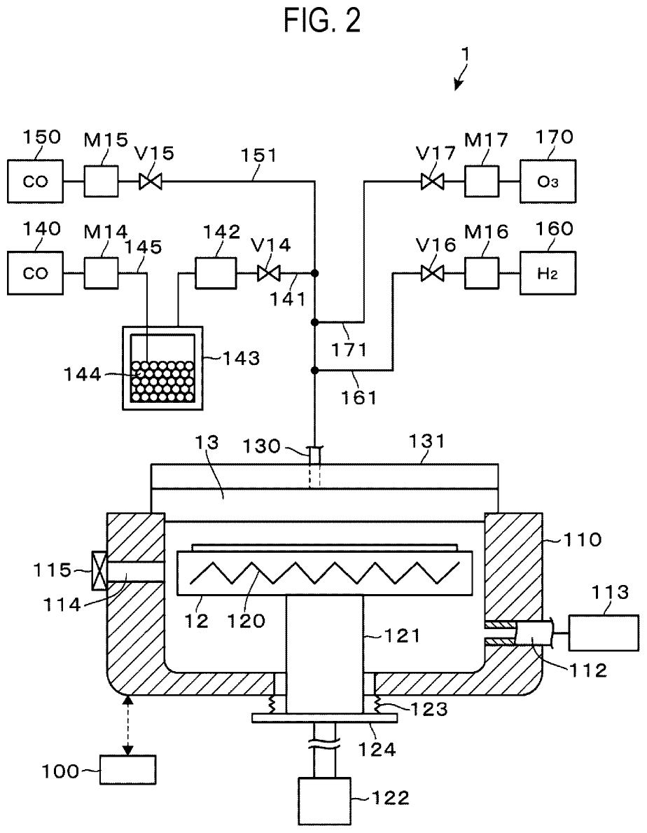

Hereinafter, a configuration example of a film forming apparatus 1, which is an apparatus for embedding ruthenium into a recess, will be described with reference to FIG. 2.

### Film Forming Apparatus

FIG. 2 is a longitudinal-sectional side view illustrating an overall configuration of the film forming apparatus 1. The film forming apparatus 1 of this embodiment is configured as an apparatus that continuously supplies a ruthenium raw material gas to a surface of the wafer W and forms a ruthenium film by a thermal chemical vapor deposition (CVD) method to embed ruthenium into a recess.

In the film forming apparatus 1 illustrated in FIG. 2, a processing container 110 is a substantially cylindrical container with an open upper surface. A lid 131 is arranged to airtightly close the opening of the processing container 110 and support a gas shower head 13 (to be described later) at the side of an upper surface of the gas shower head 13.

An exhaust line 112 is connected to a lateral side of a lower portion of the processing container 110. An evacuator 113 including a pressure regulating valve composed of, for example, a butterfly valve, is connected to the exhaust line 112, and is configured to reduce an internal pressure of the processing container 110 to a preset pressure.

A loading/unloading port 114 is formed in the lateral side of the processing container 110 to load or unload the wafer W with respect to a vacuum transfer chamber (not illustrated). The loading/unloading port 114 is opened or closed by a gate valve 115.

Further, a stage 12 is provided inside the processing container 110 to hold the wafer W substantially horizontally. For example, the stage 12 is formed in a disc shape. A heater 120, which serves as a heater for heating the wafer W, is buried in the stage 12. The heater 120 is constituted with, for example, a sheet-shaped resistance heating element, and generates heat by being supplied with power from a power supply (not illustrated), thus heating the wafer W placed on the stage 12.

Further, a support 121, which is formed as a downwardly-extending pillar, is connected to the center of a lower surface of the stage 12. A lower end portion of the support 121 penetrates a bottom portion of the processing container 110 and is connected to an elevating plate 124 arranged below the processing container 110. The elevating plate 124 is supported by an elevating shaft of an elevator 122 at a lower surface of the elevating plate 124. A bellows 123 is provided between the processing container 110 and the elevating plate 124 to cover the periphery of the support 121. The bellows 123 keeps the interior of the processing container 110 airtight.

In the above-described configuration, when the elevating plate 124 is raised or lowered by the elevator 122, the stage 12 is raised or lowered between a processing position and a delivery position of the wafer W set below the processing position. The wafer W is delivered to and from a transfer mechanism (not illustrated) by delivery pins provided in the stage 12. Here, the description of the delivery pins is omitted.

The gas shower head 13 is provided at a position facing the wafer W placed on the stage 12. As described above, the gas shower head 13 of this example is supported by the lid 131 closing the opening of the upper surface of the processing container 110. For example, the gas shower head 13 includes a diffusion chamber for diffusing a gas and multiple discharge holes for discharging the gas toward the wafer W. In FIG. 2, the description of these diffusion chamber and discharge holes is omitted.

A downstream end of a gas supply path 130 is connected to the gas shower head 13. A raw material gas supply pipe 141 is joined with an upstream of the gas supply path 130 to supply a ruthenium raw material gas. The raw material gas supply pipe 141 is provided with a valve V14 and a flow meter 142 in order from the downstream. An upstream end of the raw material gas supply pipe 141 is connected to a raw material container 143. The raw material container 143 is configured to be heated by a heater (not illustrated), and accommodates solid dodecacarbonyltriruthenium (Ru₃(CO)₁₂) as a ruthenium raw material 144 therein. In addition, the ruthenium raw material 144 is not limited to Ru₃(CO)₁₂, but may include, for example, bisethylcyclopentadienylruthenium (Ru(EtCₚ)₂).

The raw material container 143 is provided such that one end of a carrier gas supply pipe 145 is inserted into the raw material container 143. The other end of the carrier gas supply pipe 145 is connected to a gas source 140 for a CO gas, which is a carrier gas, via a flow regulator M14. The raw material gas supply pipe 141, the carrier gas supply pipe 145, the raw material container 143, the gas source 140 and the like constitute a ruthenium raw material supplier of this example.

In the above-described configuration, supply flow rates of the carrier gas (CO gas) and Ru₃(CO)₁₂ supplied to the processing container 110 via the gas shower head 13 are adjusted by adjusting a heating temperature of the ruthenium raw material 144 in the raw material container 143 and a supply flow rate of the CO gas supplied from the gas source 140.

Further, the gas supply path 130 described above may be configured such that a CO gas, which is a reaction adjustment gas, may be supplied thereto. In the film forming apparatus 1 illustrated in FIG. 2, a CO gas supply pipe 151 is joined with the gas supply path 130 to supply the CO gas. The CO gas supply pipe 151 is provided with a flow regulator M15 and a valve V15 in order from upstream. An upstream end of the CO gas supply pipe 151 is connected to a CO gas source 150.

Further, an ozone gas supply pipe 171 is joined with the gas supply path 130 to supply an ozone gas for etching the first ruthenium film 31. The ozone gas supply pipe 171 is provided with a flow regulator M17 and a valve V17 in order from upstream, and an upstream end thereof is connected to an ozone gas source 170. The ozone gas supply pipe 171, the ozone gas source 170 and the like constitute an ozone gas supplier of this example.

In addition, a hydrogen gas supply pipe 161 is joined with the gas supply path 130 to supply a hydrogen gas used to remove a reaction product generated when etching the first ruthenium film 31. The hydrogen gas supply pipe 161 is provided with a flow regulator M16 and a valve V16 in order from upstream. An upstream end of the hydrogen gas supply pipe 161 is connected to a hydrogen gas source 160. The hydrogen gas supply pipe 161, the hydrogen gas source 160, the flow regulator M16, and the valve V16 constitute a hydrogen gas supplier of this example.

The film forming apparatus 1 includes a controller 100 for controlling the delivery of the wafer W loaded or unloaded from or to the vacuum transfer chamber and the operation of each part constituting the film forming apparatus 1. The controller 100 is constituted with, for example, a computer equipped with a CPU and a storage (both of which are not illustrated). The storage stores a program incorporating a group of steps (commands) relating to the control necessary for ruthenium film formation. This program is stored in a storage medium such as a hard disk, a compact disk, a magnet-optical disk, a memory card, a non-volatile memory and the like, and is installed in the computer from the storage medium.

### Film Formation Process

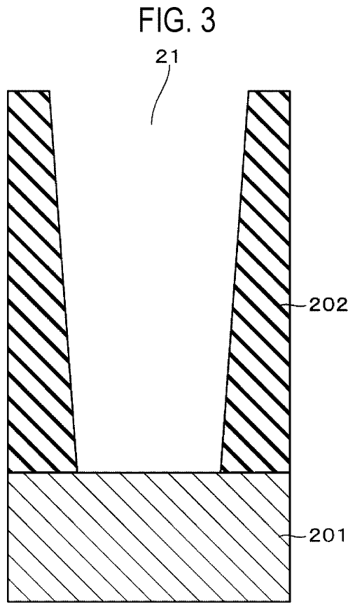

A process of embedding ruthenium into a recess formed in the insulation film 202 on the wafer W using the film forming apparatus 1 configured as above will be described with reference to FIGS. 3 to 8. FIGS. 3 to 8 schematically illustrate the embedding regions 3A to 3C illustrated in FIGS. 1A and 1B, and illustrate states where a recess 21 is formed in the insulation film 202 on an underlying film 201, respectively.

A case where the underlying film 201 corresponds to a “metal-containing film” of this example and is selected from the group consisting of a titanium silicide (TiSiₓ) film, a ruthenium (Ru) film, a tungsten (W) film, a copper (Cu) film, a titanium (Ti) film, and a ruthenium oxide (RuO₂) film, may be exemplified. Further, a case where the insulation film 202 is a silicon oxide (SiO₂) film or a silicon nitride (SiN) film, may be exemplified.

First, the wafer W, which is a processing target taken out from a carrier (not illustrated) accommodating a plurality of wafers W, is transferred to the film forming apparatus 1 via the vacuum transfer chamber. At this time, a pre-processing device (not illustrated) connected to the vacuum transfer chamber may perform a process of removing a metal oxide film (natural oxide film) covering a surface of the underlying film 201 (in an operation of removing the metal oxide film). Examples of the process of removing the metal oxide film may include a chemical oxide removal (COR) using a hydrogen fluoride (HF) gas and an ammonia (NH₃) gas to remove the metal oxide film, and a post heat treatment (PHT) for heating and sublimating a reaction product generated during COR to remove the same.

Once the wafer W as the processing target is transferred, the gate valve 115 of the film forming apparatus 1 is open, and the wafer W is loaded into the processing container 110 using a wafer transfer mechanism (not illustrated) provided in the vacuum transfer chamber. The stage 12 is awaited in a state of being lowered to the delivery position in the processing container 110, and the wafer W is delivered to the stage 12 via the delivery pins (not illustrated). Then, the wafer transfer mechanism is retracted, the gate valve 115 is closed, and the internal pressure of the processing container 110 is adjusted. Further, while raising the stage 12 from the delivery position to the processing position, the wafer W on the stage 12 is heated to 150 degrees C. within the range of 130 to 200 degrees C. by the heater 120.

As schematically illustrated in FIG. 3, the recess 21 is formed in the insulation film 202 on the surface of the wafer W placed on the stage 12. An upper surface of the underlying film 201, which is the “metal-containing film” after the removal of the metal oxide film, is exposed at the bottom portion of the recess 21.

Subsequently, the carrier gas is supplied from the gas source 140 to the raw material container 143 heated to a predetermined temperature. Through this operation, a Ru₃(CO)₁₂ gas sublimated from the ruthenium raw material 144 is picked up and is supplied together with the carrier gas to the processing container 110 from the gas shower head 13. At this time, the CO gas, which is a reaction adjustment gas, may be supplied to the gas shower head 13 from the CO gas source 150 connected in parallel to the raw material container 143. The CO gas functions to suppress the decomposition of Ru₃(CO)₁₂ and to adjust a film formation rate of a ruthenium film.

By the above-described operation, Ru₃(CO)₁₂ decomposes on the heated wafer W inside the processing container 110, and ruthenium deposits on the surface of the wafer W. As ruthenium deposits, the first ruthenium film 31 is formed so that the embedding of ruthenium into the recess 21 progresses (in an operation of forming the first ruthenium film).

Here, the metal-containing film constituting the underlying film 201, such as a titanium silicide film, a ruthenium film, or a tungsten film, exhibits a higher selectivity for the formation of the first ruthenium film 31 compared to a silicon oxide film or a silicon nitride film constituting the insulation film 202. Therefore, there is a tendency for the film formation rate of ruthenium at the bottom portion of the recess 21 to be greater than the film formation rate of ruthenium at the sidewall of the recess 21. In FIG. 4, a difference in film formation rate is schematically expressed by differences between lengths of dashed arrows.

Further, as described above, there is a tendency for film formation to preferentially progress near an opening rather than the interior of the recess 21.

Due to such film formation characteristics, as illustrated in FIG. 4, in the operation of forming the first ruthenium film, the formation of the first ruthenium film 31 progresses while leaving a vertically elongated space. Further, a width of the opening becomes narrower near the opening of the recess 21 while leaving the aforementioned elongated space. When the formation of the first ruthenium film 31 continues in this state, the opening may be blocked, which may cause the formation of voids in the ruthenium 30a to 30c embedded in the recess 21.

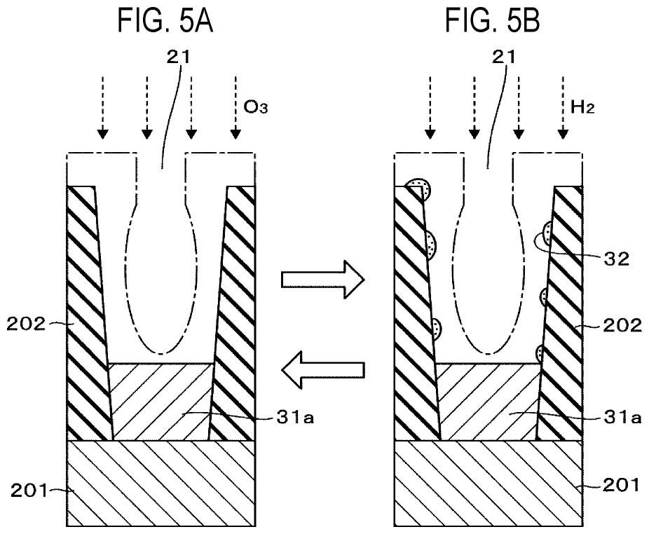

Therefore, in the film forming apparatus 1 of this example, after initiating the formation of the first ruthenium film 31, the supply of the Ru₃(CO)₁₂ gas and the CO gas is stopped at a preset timing to stop the formation of the first ruthenium film 31. Then, for example, while maintaining the heating temperature of the wafer W at 150 degrees C. within the range of 130 to 200 degrees C., the ozone gas is supplied into the processing container 110 to partially etch a ruthenium 31a at the bottom portion of the recess (FIG. 5A, in an operation of etching the first ruthenium film). In addition, in the descriptions of FIGS. 5A to 8, the first ruthenium film 31 after etching will be referred to as a “bottom-side ruthenium 31a”.

In the heating temperature range described above, when the ozone gas reacts with solid ruthenium, gaseous RuO₄ and solid RuO₂ are generated. The gaseous RuO₄ is discharged from the exhaust line 112 outward of the processing container 110. Further, most of the solid RuO₂ is discharged as fine particles carried by an exhaust stream outward of the processing container 110. On the other hand, some of the solid RuO₂ adheres as a reaction product 32 to the surface of the underlying film 201.

Therefore, during the etching of the first ruthenium film 31, the film forming apparatus 1 of this example alternately repeats the etching of the first ruthenium film 31 by the supply of the ozone gas and the removal of the reaction product 32 by the supply of the hydrogen gas to the wafer W. By supplying the hydrogen gas, RuO₄ is reduced and returned back to the state of ruthenium (Ru), resulting in the removal of the reaction product 32 (FIG. 5B). Subsequently, the reduced ruthenium is removed from the surface of the underlying film 201 by the etching during the supply of the ozone gas.

Here, in FIGS. 5A and 5B, the contour of the longitudinal cross-sectional shape of the first ruthenium film 31 before initiating the etching is indicated by a one-dot dashed line. In the example illustrated in these drawings, the supply of the ozone gas is initiated at a timing before the opening of the recess 21 is blocked to progress the etching of the first ruthenium film 31. However, a progress situation of the first ruthenium film 31 may vary between multiple recesses 21 formed in the surface of the wafer W. Accordingly, the first ruthenium film 31 may be formed faster in some of the recesses 21, so that the openings of these recesses 21 may already be blocked while leaving voids at the initiation time of the supply of the ozone gas. Even in this case, the same processing as in FIGS. 5A and 5B progresses after the first ruthenium film 31 forming a blocking portion is etched by the ozone gas.

In this way, the etching is performed until the sidewall of the recess 21 (the insulation film 202) is exposed while leaving ruthenium (the bottom-side ruthenium 31a) at the bottom portion of the recess 21 on the underlying film 201. The “bottom portion” used therein may exemplify a range below half the depth of the recess 21. Further, the removal range of the first ruthenium film 31 by the etching may be exemplified as a case where the entire portion forming the aforementioned “vertically elongated space” is removed.

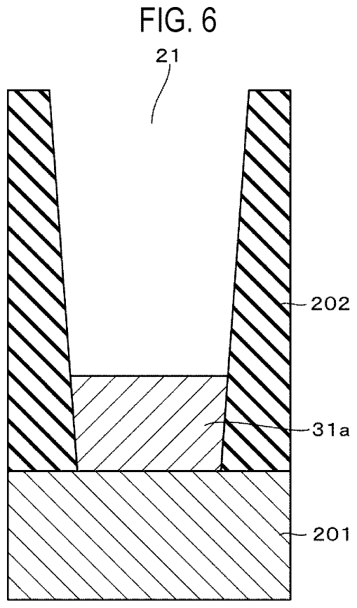

By performing the etching of the first ruthenium film 31 using the ozone gas for a preset time as described above, a structure is obtained where the sidewall of the recess 21 is exposed while leaving the bottom-side ruthenium 31a at the bottom portion of the recess 21 (FIG. 6). In addition, the removal range of the first ruthenium film 31 by the etching may be set slightly higher so that a depressed portion corresponding to a lower end of the aforementioned “vertically elongated space” is left at an upper surface of the bottom-side ruthenium 31a illustrated in FIG. 6. Even in this case, there is no significant effect on the embedding of a second ruthenium film 31b to be described later.

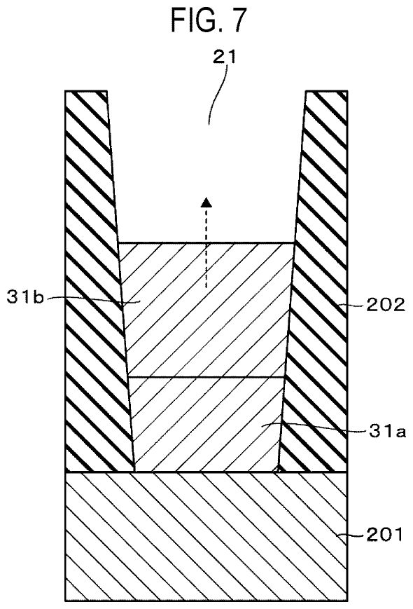

Subsequently, the film forming apparatus 1 stops the supply of the ozone gas and terminates the etching of the first ruthenium film 31. Then, for example, while maintaining the heating temperature of the wafer W at 150 degrees C. within the range of 130 to 200 degrees C., the supply of the Ru₃(CO)₁₂ gas and the CO gas is resumed to initiate the formation of the second ruthenium film 31b (FIG. 7, in an operation of forming the second ruthenium film). By performing the formation of the first ruthenium film 31, the etching of the first ruthenium film 31 using the ozone gas, and the formation of the second ruthenium film 31b at a common heating temperature, these different types of processing may be performed in the common processing container 110 without consuming the waiting time for temperature adjustment.

Further, the etching of the first ruthenium film 31 may be performed before the formation of the second ruthenium film 31b. At this time, the ozone gas is used as an etching gas. By using the ozone gas, a modification effect of increasing a difference in film formation rate between the upper surface of the bottom-side ruthenium 31a and the sidewall surface of the recess 21, i.e., the surface of the insulation film 202, may be obtained.

In other words, the reaction product 32 is removed on the surface of the etched bottom-side ruthenium 31a by the supply of the hydrogen gas as described above, so that ruthenium remains exposed. Here, it is understood that the etching using the ozone gas acts to increase a surface roughness of the bottom-side ruthenium 31a, compared to the state where the first ruthenium film 31 is formed. As a result, an adsorption area of active species generated from the Ru₃(CO)₁₂ gas increases, leading to the effect of increasing the film formation rate of the second ruthenium film 31b.

On the other hand, the ozone gas reacts with dangling bonds of the silicon oxide film or the silicon nitride film constituting the insulation film 202 to form Si—O bonds, thus acting to reduce the content of dangling bonds. As a result, the adsorption of active species generated from the Ru₃(CO)₁₂ gas to the surface of the insulation film 202 modified by the ozone gas is inhibited, which significantly decreases the film formation rate of the second ruthenium film 31b.

As described above with reference to FIG. 4, there is a tendency for the film formation rate of ruthenium at the bottom portion of the recess 21 to be greater than the film formation rate of ruthenium at the sidewall of the recess 21 between the metal-containing film constituting the underlying film 201 and the insulation film 202. Further, the sidewall surface and bottom surface of the recess 21 are modified during the etching of the second ruthenium film 31b using the ozone gas as described above. As a result, the difference in film formation rate between the sidewall and the bottom portion of the recess 21 is greater during the period of forming the second ruthenium film 31b than during the period of forming the first ruthenium film 31.

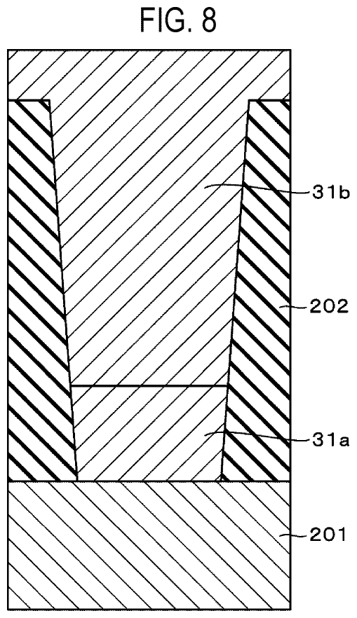

In particular, the formation of the second ruthenium film 31b hardly progresses at the surface of the insulation film 202 modified by the ozone gas. As illustrated in FIG. 7, a high anisotropic film formation process may be performed mainly from the upper surface of the bottom-side ruthenium 31a to progress the formation of the second ruthenium film 31b. Then, by the high anisotropic film formation process, the second ruthenium film 31b is formed upward from the surface of the bottom-side ruthenium 31a to fill the interior of the recess 21, which makes it possible to embed ruthenium into the recess while preventing the formation of voids (FIG. 8).

In this way, after the second ruthenium film 31b is formed for a preset period of time, the supply of the Ru₃(CO)₁₂ gas and the CO gas is stopped, and the heating of the wafer W is stopped. Subsequently, the stage 12 is lowered from the processing position to the delivery position, and the wafer W is unloaded from the processing container 110 in an order opposite to the loading. Then, the processed wafer W is transferred by the vacuum transfer chamber (not illustrated) or the like, and is accommodated in its original carrier.

According to the film forming apparatus 1 of the present embodiment, the formation of ruthenium film (the first ruthenium film 31 and the second ruthenium film 31b) embedded into the recess 21 is performed through two divided operations. Further, the first ruthenium film 31 is partially removed by etching using the ozone gas between such two film formation operations. This makes it possible to embed ruthenium into the recess 21 while preventing the formation of voids.

Here, for example, the process of supplying the ozone gas to the recess 21 before forming the first ruthenium film 31 to modify the surface of the insulation film 202 may cause the formation of an oxide film on the surface of the insulation film 202 exposed at the bottom portion of the recess 21. As a result, a contact resistance with ruthenium embedded into the recess 21 may be increased, which is an undesirable factor. By stacking the first ruthenium film 31 on the insulation film 202 from which the metal oxide film has been previously removed by COR or PHT, and then modifying the surface of the bottom-side ruthenium 31a or the insulation film 202 using the ozone gas, it is possible to embed ruthenium while suppressing the increase in contact resistance and the formation of voids.

### Variations

Here, it is not essential to perform the formation of the first ruthenium film 31, the etching of the first ruthenium film 31 using the ozone gas, and the formation of the second ruthenium film 31b at the common heating temperature as described in the above examples. For example, in a case where an optimal processing temperature is varied between the formation of the first ruthenium film 31, the formation of the second ruthenium film 31b, and the etching of the first ruthenium film 31 using the ozone gas, the heating temperature of the wafer W may be changed for each processing. Further, processing containers for various processing may be connected to a common vacuum transfer chamber, and the various processing may be performed inside a plurality of different processing containers. In this case, the entire configuration including the vacuum transfer chamber and the plurality of processing containers constitutes a ruthenium embedding apparatus of the present disclosure.

In addition, it is also not essential to alternately repeat the etching of the first ruthenium film 31 using the ozone gas and the removal of the reaction product 32 using the hydrogen gas as in the example described with reference to FIGS. 5A and 5B. For example, in a case where the influence of the reaction product 32 is minimal, after the etching of the first ruthenium film 31 using the ozone gas is performed for a predetermined period of time, the removal of the reaction product 32 using the hydrogen gas may be performed only once, or the supply of the hydrogen gas may be omitted to bypass the removal of the reaction product 32.

It should be noted that the embodiments disclosed herein are exemplary in all respects and are not restrictive. The above-described embodiments may be omitted, replaced or modified in various forms without departing from the scope and spirit of the appended claims.

### Example

<Experiment> The ruthenium (Ru) film, the silicon oxide (SiO₂) film and the like were formed on the surface of a blanket wafer, and a change in film formation rate of the Ru film before and after performing a modification using the ozone gas was measured.

### A. Experimental Conditions

### Reference Example

The blanket wafer with each of the Ru film, the SiO₂ film, and the tungsten (W) film formed on the surface thereof was prepared, and the ruthenium film was formed using the Ru₃(CO)₁₂ gas. A film formation cycle in which the Ru₃(CO)₁₂ gas is supplied for 35 seconds was repeated 2 to 4 times, and a film thickness of the Ru film in each cycle was measured to check a change in film formation rate. The heating temperature of the wafer W in the film formation cycle was 150 degrees C.

### Example

The blanket wafer with each of the Ru film and the SiO₂ film formed on the surface thereof was processed using the ozone gas, and then the Ru film was formed under the same conditions as those in the Reference Example. The heating temperature of the wafer W during the processing using the ozone gas was 150 degrees C.

### B. Experiment Results

FIG. 2 illustrates the results of the Reference Example, and FIG. 3 illustrates the results of the Example. In each graph, the horizontal axis represents the number of repetition times of the film formation cycle, and the vertical axis represents the film thickness of the Ru film.

In the Reference Example in which the processing using the ozone gas was not performed, there is no significant difference between the amount of the Ru film (corresponding to the first ruthenium film 31) formed on the Ru film and the amount of the Ru film formed on the SiO₂ film (corresponding to the insulation film 202) for each repetition of the film formation cycle. Further, since the amount of the Ru film formed on the W film (corresponding to the underlying film 201) increases significantly at the same number of film formation times (4 times), it can be appreciated that it is possible to improve the film formation rate by selecting a metal-containing film constituting the underlying film 201. Accordingly, by initiating the formation of the first ruthenium film 31 from the state where the underlying film 201 is exposed, the film formation rate of ruthenium at the bottom portion of the recess 21 may be made greater than that at the sidewall of the recess 21.

On the other hand, in the Example in which the processing using the ozone gas was performed, the amount of the Ru film formed on the SiO₂ film decreases for each repetition of the film formation cycle compared to the Reference Example. In contrast, the amount of the Ru film formed on the Ru film increases significantly compared to the Reference Example. Further, including the origin where the film thickness is zero, it can be said that the processing using the ozone gas significant increases the film formation rate of the Ru film (corresponding to the second ruthenium film 31b) on the Ru film (corresponding to the first ruthenium film 31) compared to the film formation rate of the Ru film on the SiO₂ film (corresponding to the insulation film 202).

### EXPLANATION OF REFERENCE NUMERALS

W: wafer, 1: film forming apparatus, 110: processing container, 143: raw material container, 144: ruthenium raw material, 160: ozone gas source

1-17: (canceled)

18. A method of embedding ruthenium into a recess formed in an insulation film on a substrate, the method comprising:
forming a first ruthenium film by supplying a ruthenium raw material to the substrate so that the ruthenium is embedded into the recess;
after stopping the forming the first ruthenium film, etching the first ruthenium film by supplying an ozone gas to the substrate until a sidewall of the recess is exposed while leaving the ruthenium embedded at a bottom portion of the recess; and
subsequently, forming a second ruthenium film by supplying the ruthenium raw material to the substrate so that the recess is filled with ruthenium.

19. The method of claim 18, wherein a first film formation rate of the ruthenium at the bottom portion is greater than a second film formation rate of the ruthenium at the sidewall of the recess, and a difference between the first film formation rate at the bottom portion and the second film formation rate at the sidewall is greater in the forming the second ruthenium film than in the forming the first ruthenium film.

20. The method of claim 18, wherein, in the etching the first ruthenium film, the etching the first ruthenium film by supplying the ozone gas and removing a reaction product produced by reaction of ozone with the ruthenium by supplying a hydrogen gas to the substrate are alternately repeated.

21. The method of claim 18, wherein the insulation film is formed on a metal-containing film, and the first ruthenium film is formed on the metal-containing film exposed at the bottom portion of the recess.

22. The method of claim 21, comprising: removing a metal oxide film covering the metal-containing film exposed at the bottom portion of the recess before performing the forming the first ruthenium film.

23. The method of claim 21, wherein the metal-containing film has a higher film formation selectivity than the insulation film, and the first film formation rate of the ruthenium at the bottom portion of the recess is greater than the second film formation rate of the ruthenium at the sidewall of the recess.

24. The method of claim 23, wherein the metal-containing film is selected from the group consisting of a titanium silicide film, a ruthenium film, a tungsten film, a copper film, a titanium film, and a ruthenium oxide film.

25. The method of claim 18, wherein the insulation film is a silicon oxide film or a silicon nitride film.

26. The method of claim 18, wherein the forming the first ruthenium film, the etching the first ruthenium film, and the forming the second ruthenium film are performed in a state where the substrate is heated to a common temperature within a range of 130 to 200 degrees C.

27. The method of claim 19, wherein, in the etching the first ruthenium film, the etching the first ruthenium film by supplying the ozone gas and removing a reaction product produced by reaction of ozone with the ruthenium by supplying a hydrogen gas to the substrate are alternately repeated.

28. The method of claim 24, wherein the insulation film is a silicon oxide film or a silicon nitride film.

29. An apparatus for embedding ruthenium into a recess formed in an insulation film on a substrate, the apparatus comprising:
a processing container in which the substrate is accommodated;
a ruthenium raw material supplier configured to supply a ruthenium raw material to the processing container;
an ozone gas supplier configured to supply an ozone gas to the processing container; and
a controller,
wherein the controller is configured to output a first control signal for executing:
a step of forming a first ruthenium film by supplying a ruthenium raw material from the ruthenium raw material supplier to the substrate inside the processing container so that the ruthenium is embedded into the recess;
after stopping the forming the first ruthenium film, a step of etching the first ruthenium film by supplying an ozone gas from the ozone gas supplier to the substrate until a sidewall of the recess is exposed while leaving the ruthenium embedded at a bottom portion of the recess; and
subsequently, a step of forming a second ruthenium film by supplying the ruthenium raw material from the ruthenium raw material supplier to the substrate so that the recess is filled with ruthenium.

30. The apparatus of claim 29, wherein a first film formation rate of the ruthenium at the bottom portion is greater than a second film formation rate of the ruthenium at a sidewall of the recess, and a difference between the first film formation rate at the bottom portion and the second film formation rate at the sidewall is greater in the forming the second ruthenium film than in the forming the first ruthenium film.

31. The apparatus of claim 29, comprising: a hydrogen gas supplier configured to supply a hydrogen gas to the processing container,
wherein the controller outputs a second control signal to alternately repeat, in the etching the first ruthenium film, the etching the first ruthenium film by supplying the ozone gas and removing a reaction product produced by reaction of ozone with the ruthenium by supplying the hydrogen gas to the substrate.

32. The apparatus of claim 29, wherein the insulation film is formed on a metal-containing film, and the first ruthenium film is formed on the metal-containing film exposed at the bottom portion of the recess.

33. The apparatus of claim 32, wherein the metal-containing film has a higher film formation selectivity than the insulation film, and the film formation rate of the ruthenium at the bottom portion of the recess is greater than the film formation rate of the ruthenium at the sidewall of the recess.

34. The apparatus of claim 33, wherein the metal-containing film is selected from a group consisting of a titanium silicide film, a ruthenium film, a tungsten film, a copper film, a titanium film, and a ruthenium oxide film.

35. The apparatus of claim 29, wherein the insulation film is a silicon oxide film or a silicon nitride film.

36. The apparatus of claim 29, comprising: a heater configured to heat the substrate inside the processing container,
wherein the controller outputs a third control signal to execute the forming the first ruthenium film, the etching the first ruthenium film, and the forming the second ruthenium film in a state where the substrate is heated to a common temperature within a range of 130 to 200 degrees C. by the heater.

37. The apparatus of claim 31, wherein the insulation film is formed on a metal-containing film, and the first ruthenium film is formed on the metal-containing film exposed at the bottom portion of the recess.
